(19) United States
(12) Patent Application Publication
(10) Pub. No.: US 2026/0337749 A1
(43) Pub. Date: Oct. 29, 2026

(54) MASK ASSEMBLY, AND METHOD FOR MANUFACTURING DISPLAY APPARATUS AND ELECTRONIC DEVICE INCLUDING THE DISPLAY APPARATUS

(71) Applicant: Samsung DIsplay Co., Ltd., Yongin-si (KR)

(72) Inventor: Sungwoon Kim, Yongin-si (KR)

(21) Appl. No.: 19/655,199

(22) Filed: Apr. 22, 2026

(30) Foreign Application Priority Data
Apr. 25, 2025 (KR) 10-2025-0054801

(51) Int. Cl. C23C 14/04; H10K 59/12; H10K 71/16

(52) U.S. Cl. CPC C23C 14/042; H10K 59/1201; H10K 71/166

(57) ABSTRACT

A mask sheet includes a plurality of deposition holes, and a mask frame supporting the mask sheet, where each of the deposition holes includes a main hole and a sub-hole defined radially outward from the main hole.

### CROSS-REFERENCE TO RELATED APPLICATION

This application claims priority to Korean Patent Application No. 10-2025-0054801, filed on Apr. 25, 2025, and all the benefits accruing therefrom under 35 U.S.C. §119, the content of which in its entirety is herein incorporated by reference.

### BACKGROUND

### 1. Field

Embodiments relate to a mask assembly, a method for manufacturing a display apparatus, and a method for manufacturing an electronic device, and more specifically, to a mask assembly, a method for manufacturing a display apparatus, and a method for manufacturing an electronic device, in which deposition quality may be improved.

### 2. Description of the Related Art

Recently, electronic devices are widely used. Electronic devices are utilized in various forms, such as mobile electronic devices and stationary electronic devices, and these electronic devices include a display apparatus that may provide visual information such as images or videos to users to support various functions.

A display apparatus visually displays data, and is formed by depositing various layers such as organic layers, inorganic layers, and metal layers. A deposition material may be deposited on a display substrate to form a plurality of layers of the display apparatus. That is, a deposition material may be sprayed from a deposition source and deposited on the display substrate through a mask assembly.

### SUMMARY

In forming the plurality of layers, it is desired to prevent a shadow phenomenon to improve deposition quality.

Embodiments may provide a mask assembly, a method for manufacturing a display apparatus, and a method for manufacturing an electronic device, in which deposition quality may be improved.

However, this is merely illustrative embodiments, and the scope of the disclosure is not limited thereto.

Additional features will be set forth in part in the description which follows and, in part, will be apparent from the description, or may be learned by practice of the presented embodiments of the disclosure.

In an embodiment of the disclosure, a mask sheet in which a plurality of deposition holes are defined, and a mask frame supporting the mask sheet, where each of the plurality of deposition holes includes a main hole and a sub-hole defined radially outward from the main hole.

In an embodiment, the sub-hole may be disposed to surround a peripheral edge of the main hole.

In an embodiment, the sub-hole may be provided in plural, and the plurality of sub-holes may be spaced apart along a perimeter of the main hole.

In an embodiment, the main hole may have a polygonal shape, the plurality of sub-holes may be provided to correspond to a number of edges of the polygon, and the plurality of sub-holes may be disposed to respectively face the edges of the polygon.

In an embodiment, the main hole may have a circular shape, and the sub-hole may have a segmented ring shape.

In an embodiment, the sub-hole is provided in plural, and the plurality of sub-holes may include a first sub-hole defined to surround the main hole and a second sub-hole defined outside the first sub-hole to surround the first sub-hole.

In an embodiment, a radial width of the main hole may be greater than a radial width of the sub-hole.

In an embodiment, a distance from a perimeter of the main hole to a perimeter of the sub-hole may be less than a radial width of the sub-hole.

In an embodiment of the disclosure, a method for manufacturing a display apparatus, includes disposing a display substrate and a deposition source to face the display substrate, disposing a mask assembly between the display substrate and the deposition source, and depositing a deposition material from the deposition source on a deposition area on the display substrate through a deposition hole of the mask assembly, where the deposition hole corresponding to the deposition area includes a main hole and a sub-hole defined radially outward from the main hole, and the main hole and the sub-hole are disposed within the deposition area in a plan view.

In an embodiment, the method may further include forming an emission layer of a sub-pixel by depositing the deposition material in the deposition area.

In an embodiment, the emission layer of the sub-pixel may be formed by depositing the deposition material that passed through the main hole and the sub-hole in the deposition area.

In an embodiment, the display substrate may include a pixel electrode disposed below the emission layer of the sub-pixel, and a size of the main hole may be identical to a size of the pixel electrode.

In an embodiment, an outer perimeter of the sub-hole may overlap a perimeter of the deposition area.

In an embodiment, an outer perimeter of the sub-hole may be spaced inward from a perimeter of the deposition area.

In an embodiment, the sub-hole may be disposed to surround a peripheral edge of the main hole.

In an embodiment, a plurality of sub-holes may be provided, and the plurality of sub-holes may be spaced apart along a perimeter of the main hole.

In an embodiment, the main hole may have a polygonal shape, a plurality of sub-holes may be provided to correspond to a number of edges of the polygon, and each of the plurality of sub-holes may be disposed to face each of the edges of the polygon.

In an embodiment, the main hole may have a circular shape, and the sub-hole may have a segmented ring shape.

In an embodiment, the plurality of sub-holes may include a first sub-hole defined to surround the main hole and a second sub-hole defined outside the first sub-hole to surround the first sub-hole.

In an embodiment of the disclosure, a method for manufacturing an electronic device, includes disposing a display substrate and a deposition source to face the display substrate, disposing a mask assembly between the display substrate and the deposition source, and depositing a deposition material from the deposition source on a deposition area on the display substrate through a deposition hole of the mask assembly, where the deposition hole corresponding to the deposition area includes a main hole and a sub-hole defined radially outward from the main hole, and the main hole and the sub-hole are disposed within the deposition area.

Other features and advantages other than those described above will become apparent from the following detailed description, claims, and drawings.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a block diagram of an embodiment of an electronic device;

FIGS. 2 to 4 are schematic diagrams of embodiments of electronic devices;

FIG. 5 is a schematic perspective view of an embodiment of a display apparatus;

FIG. 6 is an equivalent circuit diagram of an embodiment of one pixel circuit included in a display apparatus;

FIG. 7 is a schematic cross-sectional view of an embodiment of a display apparatus;

FIG. 8 is a cross-sectional view showing an embodiment of a manufacturing apparatus for a display apparatus;

FIG. 9 is a schematic plan view of an embodiment of a mask assembly;

FIG. 10 is a schematic cross-sectional view of an embodiment of a mask assembly taken along line X-X' of FIG. 9;

FIG. 11 is a schematic plan view of an embodiment of a sheet portion;

FIG. 12 is a schematic cross-sectional view of an embodiment of a sheet portion taken along line XII-XII’ of FIG. 11;

FIG. 13 is a schematic cross-sectional view of a sheet portion according to a comparative example; and

FIGS. 14 to 16 are schematic plan views of embodiments of sheet portions.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

Various modifications may be applied to the illustrated embodiments, and particular embodiments will be illustrated in the drawings and described in the detailed description section. The effect and features of the illustrated embodiments, and a method to achieve the same, will be clearer referring to the detailed descriptions below with the drawings. However, the illustrated embodiments may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiment, it will be understood that although the terms "first," "second," etc. may be used herein to describe various components, these components should not be limited by these terms. These terms are only used to distinguish one component from another.

In the following embodiment, the expression of singularity in the specification includes the expression of plurality unless clearly specified otherwise in context.

In the following embodiment, it will be further understood that the terms "includes," "has," "including," and/or "having" used herein specify the presence of stated features or components, but do not preclude the presence or addition of one or more other features or components.

In the following embodiment, it will be understood that when a layer, region, or component is referred to as being "formed on" another layer, region, or component, it may be directly or indirectly formed on the other layer, region, or component. That is, for example, intervening layers, regions, or components may be present.

In the following embodiments, when layers, regions, or components are connected to each other, the layers, the regions, or the components may be directly connected to each other, or another layer, another region, or another component may be disposed between the layers, the regions, or the components and thus the layers, the regions, or the components may be indirectly connected to each other. In addition, when layers, regions, or components are electrically connected to each other, the layers, the regions, or the components may be directly electrically connected to each other, or another layer, another region, or another component may be disposed between the layers, the regions, or the components and thus the layers, the regions, or the components may be indirectly electrically connected to each other.

Sizes of elements in the drawings may be exaggerated or reduced for convenience of explanation. For example, since sizes and thicknesses of components in the drawings are arbitrarily illustrated for convenience of explanation, the following disclosure is not limited thereto.

In the following embodiments, the expression such as "A and/or B" may include A, B, or A and B. Furthermore, the expression such as "at least one of A and B" may include A, B, or A and B.

As used herein, when a wiring is referred to as "extending in a first direction or a second direction," it means that the wiring not only extends in a straight line shape but also extends in a zigzag or in a curve in the first direction or the second direction.

As used herein, "in a plan view" means that an objective portion is viewed from above. In addition, "in a cross-sectional view" means that a cross-section of an objective portion taken vertically is viewed from a lateral side. In the following embodiments, "overlapping" of a first component and a second component means that the first component is disposed above or below the second component.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an illustrative embodiment may be implemented differently, a specific process order may be performed differently from the described order. For example, two consecutively described processes may be performed substantially at the same time or performed in an order opposite to the described order, for example.

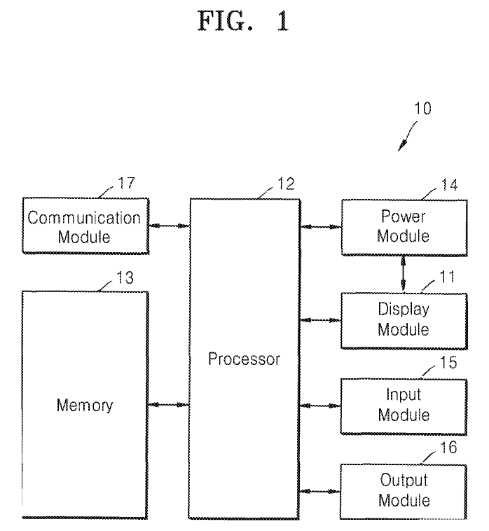

FIG. 1 is a block diagram of an embodiment of an electronic device.

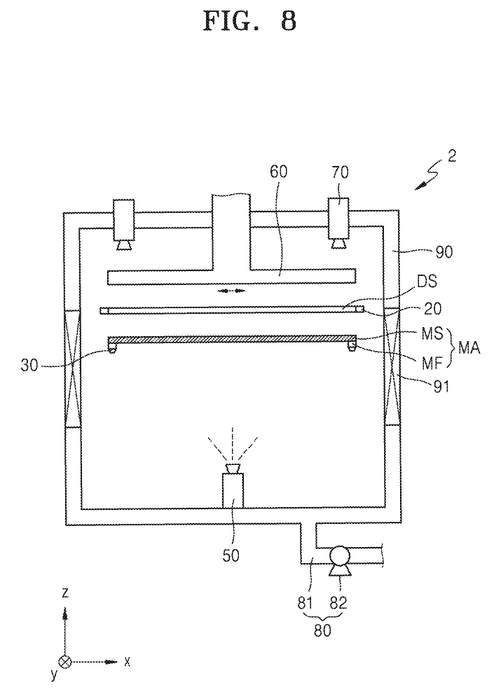

Referring to FIG. 1, an electronic device 10 may include a display module 11, a processor 12, a memory 13, and a power module 14. In an embodiment, the display module 11 may be manufactured through a manufacturing apparatus 2 (referring to FIG. 8) of a display apparatus to be described below.

The processor 12 may include at least one of a central processing unit (“CPU”), an application processor (“AP”), a graphics processing unit (“GPU”), a communication processor (“CP”), an image signal processor (“ISP”), and a controller. In an embodiment, the processor 12 may be provided by being divided into two or more from a functional or structural perspective. In an embodiment, the processor 12 may include a main processor in the form of a first driving chip including a CPU, and an auxiliary processor in the form of a second driving chip including a controller that receives a video signal from the main processor and processes the video signal to match interface specifications of the display module 11, for example.

The memory 13 may include at least one of a non-volatile memory and a volatile memory. Data information desired for operation of the processor 12 or the display module 11 may be stored in the memory 13. When the processor 12 executes an application stored in the memory 13, a video data signal and/or an input control signal are transmitted to the display module 11, and the display module 11 may process the provided signals to output video information through a display screen.

The power module 14 may include a power supply module such as a power adapter or a battery device and a power conversion module that converts power supplied by the power supply module to generate power desired for operation of the electronic device 10. Power conversion by the power conversion module may include direct current to direct current (“DC-DC”) conversion, alternating current to direct current (“AC-DC”) conversion, and direct current to alternating current (“DC-AC”) conversion, but is not limited thereto.

The electronic device 10 may further include an input module 15, a non-image output module 16, and/or a communication module 17.

The input module 15 may provide input information to the processor 12 and/or the display module 11. The input module 15 may include various sensor modules as well as physical buttons, a keyboard, and a microphone. In embodiments, sensor modules may include biosensors such as a touch sensor, a pressure sensor, a distance sensor, a position sensor, a digitizer, a motion recognition sensor, a camera sensor, a light-receiving sensor, a photoelectric conversion sensor, a temperature sensor, as well as a blood pressure sensor, a blood glucose sensor, an electrocardiogram sensor, and a heart rate sensor.

The non-image output module 16 may receive information other than images transmitted from the processor 12 and provide the same to a user. In embodiments, the non-image output module 16 may include an acoustic module, a haptic module, a light-emitting module, or the like, and may include other function modules unique to electronic devices (e.g., a cooling module of a refrigerator).

The communication module 17 is a module responsible for transmitting and receiving information between the electronic device 10 and an external device, and may include a receiver and a transmitter. The communication module 17 may include various wireless communication modules such as a mobile communication module, a Wi-Fi module, and a Bluetooth^{®} module, or various wired communication modules.

At least one of the respective components of the electronic device 10 described above may be included in a display apparatus. Also, some of individual modules functionally included in one module may be included in a display apparatus and others may be provided separately from the display apparatus. In an embodiment, a display apparatus may include the display module 11, and the processor 12, the memory 13, and the power module 14 may be provided in the form of other devices within the electronic device 10 rather than the display apparatus, for example. In another embodiment, the power module 14 may be provided in a display apparatus and may supply power to the processor 12 and the memory 13 provided in the electronic device 10 rather than the display apparatus, and the disclosure is not limited to the above examples.

Such a display apparatus may be manufactured by a manufacturing apparatus of a display apparatus to be described below in an embodiment.

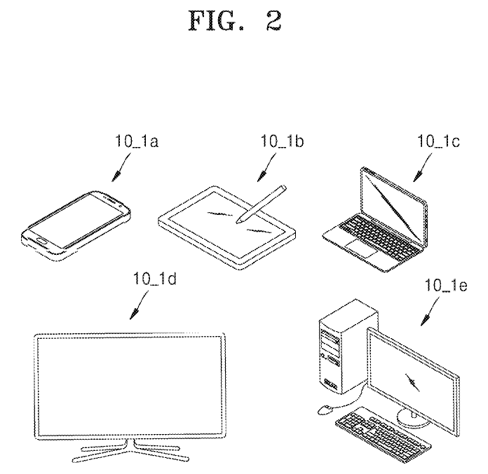

FIGS. 2-4 are schematic diagrams of embodiments of electronic devices. FIGS. 2-4 illustrate embodiments of various electronic devices to which display apparatuses in embodiments are applied.

FIG. 2 illustrates a smartphone 10_1a, a tablet personal computer 10_1b, a laptop 10_1c, a television (“TV”) 10_1d, and a desktop monitor 10_1e as embodiments of electronic devices.

The smartphone 10_1a may include an input module such as a touch sensor and a communication module in addition to the display module 11. The smartphone 10_1a may process information received through a communication module or other input modules to display information through the display module 11 of a display apparatus.

The tablet personal computer 10_1b, the laptop 10_1c, the TV 10_1d, and the desktop monitor 10_1e also include a display module and an input module similar to the smartphone 10_1a, and may further include a communication module in some cases.

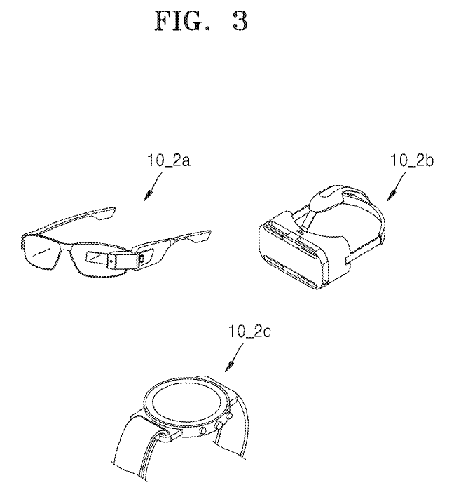

FIG. 3 illustrates a case where an electronic device including a display module is applied to a wearable electronic device. The wearable electronic device may be smart glasses 10_2a, a head mounted display 10_2b, a smart watch 10_2c, or the like.

The smart glasses 10_2a and the head mounted display 10_2b may include a display module that emits a display image and a reflector that reflects the emitted display screen to provide the same to a user's eyes, and may thus provide a virtual reality or augmented reality screen to a user.

The smart watch 10_2c includes a biosensor as an input device, and may provide biometric information recognized through the biosensor to a user through a display module.

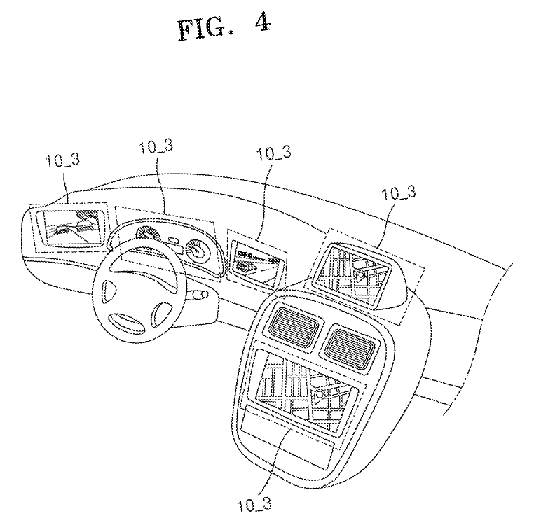

FIG. 4 illustrates a case where an electronic device including a display module is applied to a vehicle. In an embodiment, an electronic device 10_3 may be applied to an instrument panel of an automobile, a center fascia, etc., or may be applied to a center information display (“CID”) disposed on a dashboard of an automobile or a room mirror display that replaces a side mirror, for example.

Although not illustrated, electronic devices to which display apparatuses in embodiments are applied may include various home appliances that display information through display modules such as refrigerators, washing machines, dryers, air conditioners, and robot cleaners, as well as devices mainly for screen display such as billboards, electronic signboards, and gaming machines. Also, when the display module has a function of transmitting light, the display module may be applied to electronic devices such as smart windows or transparent display apparatuses that display backgrounds and display images together. Types of electronic devices according to the disclosure is not limited by the above examples, and applications of various other electronic devices not illustrated may also be possible.

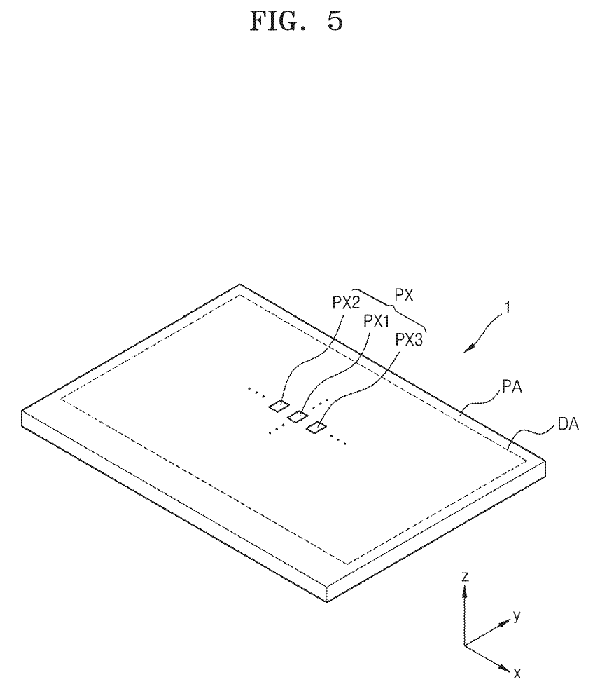

FIG. 5 is a schematic perspective view of an embodiment of a display apparatus. In an embodiment, a display apparatus 1 may be manufactured using the manufacturing apparatus 2 of a display apparatus to be described below.

Referring to FIG. 5, the display apparatus 1 may include a display area DA that implements images and a peripheral area PA that does not implement images. The display apparatus 1 may provide an image through an array of a plurality of pixels arranged two-dimensionally on an x-y plane of the display area DA. Each pixel may include different sub-pixels. Each sub-pixel may emit different colors, and may be one of a green sub-pixel, a red sub-pixel, and a blue sub-pixel, for example.

In an embodiment, the plurality of sub-pixels include a first sub-pixel PX1, a second sub-pixel PX2, and a third sub-pixel PX3, and hereinafter, for convenience of description, the case where the first sub-pixel PX1 is a green sub-pixel, the second sub-pixel PX2 is a red sub-pixel, and the third sub-pixel PX3 is a blue sub-pixel will be described.

The first sub-pixel PX1, the second sub-pixel PX2, and the third sub-pixel PX3 are areas that may emit green light, red light, and blue light, respectively, and the display apparatus 1 may provide an image using light emitted from the sub-pixels.

The peripheral area PA is an area that does not provide an image, and may surround an entirety of the display area DA. A driver or a main voltage line for providing electrical signals or power to pixel circuits may be disposed in the peripheral area PA. The peripheral area PA may include a pad which is an area where an electronic element or a printed circuit board may be electrically connected.

The display area DA may have a polygonal shape such as a rectangle, as illustrated in FIG. 5. In an embodiment, the display area DA may have a quadrangular shape, e.g., rectangular shape in which a horizontal length is greater than a vertical length, a quadrangular shape, e.g., rectangular shape in which a horizontal length is less than a vertical length, or a square shape, for example. In another embodiment, the display area DA may be circular, oval, or polygonal such as triangular or pentagonal. Also, the display apparatus 1 of FIG. 5 illustrates a flat-type flat panel display apparatus, but the display apparatus 1 may be implemented in various forms such as flexible, foldable, and rollable display apparatuses.

The display apparatus 1 may be used as a display screen of various products such as televisions, notebooks, monitors, billboards, and internet of things (“IoT”) devices, as well as portable electronic devices such as mobile phones, smart phones, tablet personal computers, mobile communication terminals, electronic notebooks, electronic books, portable multimedia players (“PMPs”), navigation systems, and ultra mobile personal computers (“UMPCs”). Also, the display apparatus 1 in an embodiment may be used in wearable devices such as smart watches, watch phones, eyewear displays, and head mounted displays (“HMDs”). Also, the display apparatus 1 in an embodiment may be used as an instrument panel of an automobile, a CID disposed on a center fascia or dashboard of an automobile, a room mirror display that replaces a side mirror of an automobile, and a display screen disposed on a rear surface of a front seat for rear seat entertainment of an automobile.

Also, although it will be described below that the display apparatus 1 includes an organic light-emitting diode (“OLED”) as a display element, the display apparatus 1 of the disclosure is not limited thereto. In an embodiment, the display apparatus 1 may be a light-emitting display apparatus including an inorganic light-emitting diode, that is, an inorganic light-emitting display. In an embodiment, the display apparatus 1 may be a quantum dot light-emitting display.

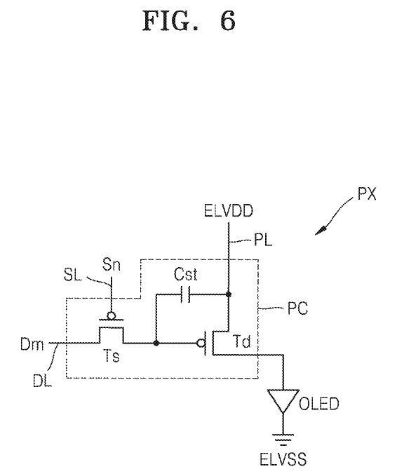

FIG. 6 is an equivalent circuit diagram of an embodiment of one pixel circuit included in a display apparatus. The pixel circuit PC may be electrically connected to a display element, and one display element may correspond to one pixel PX. In an embodiment, the display element may be an organic light-emitting diode OLED, for example.

The pixel circuit PC may include a first transistor Td, a second transistor Ts, and a storage capacitor Cst. The second transistor Ts is a switching transistor that is connected to a scan line SL and a data line DL respectively transmitting a scan signal Sn and a data signal Dm (n and m are natural numbers), and may be turned on by a switching signal input from the scan line SL to transmit a data signal input from the data line DL to the first transistor Td. The storage capacitor Cst has one end electrically connected to the second transistor Ts and an opposite end electrically connected to a driving voltage line PL, and may store a voltage corresponding to the difference between a voltage received from the second transistor Ts and a driving power voltage ELVDD supplied to the driving voltage line PL.

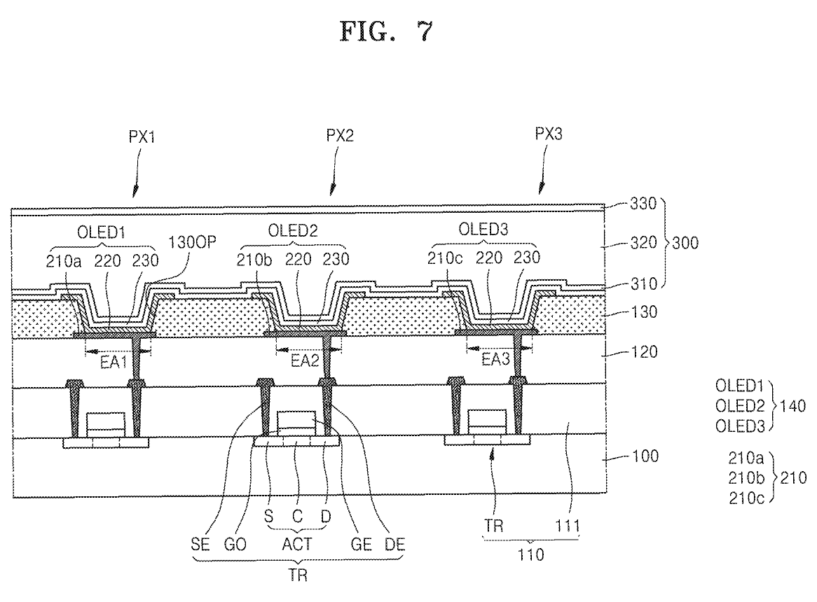

The first transistor Td is a driving transistor that is connected to the driving voltage line PL and the storage capacitor Cst, and may control the magnitude of driving current flowing from the driving voltage line PL to the organic light-emitting diode OLED in response to a voltage value stored in the storage capacitor Cst. The organic light-emitting diode OLED may emit light having a predetermined luminance according to the driving current. A counter electrode 230 (refer to FIG. 7) of the organic light-emitting diode OLED may receive an electrode power voltage ELVSS.

FIG. 6 illustrates that the pixel circuit PC includes two transistors and one storage capacitor, but the disclosure is not limited thereto. In an embodiment, the number of transistors or the number of storage capacitors may be variously changed according to a design of the pixel circuit PC, for example.

FIG. 7 is a schematic cross-sectional view of an embodiment of a display apparatus.

Referring to FIG. 7, a display apparatus 1 may include a substrate 100, a pixel circuit layer 110 including a transistor TR, a via-insulating layer 120 on the pixel circuit layer 110, a display element layer 140 disposed on the via-insulating layer 120, and an encapsulation layer 300 on the display element layer 140.

The substrate 100 may have an upper surface in a plan view extending in an x direction and a y direction. The substrate 100 may include a semiconductor material, e.g., a group IV semiconductor, a group III-V compound semiconductor, or a group II-VI compound semiconductor. That is, the substrate 100 may be a semiconductor substrate including a semiconductor material. Specifically, the substrate 100 may include silicon (Si). That is, the substrate 100 may include a silicon substrate (silicon semiconductor substrate). In an embodiment, the substrate 100 may be a silicon wafer, for example. The silicon wafer may be a monocrystalline silicon wafer, a polycrystalline silicon wafer, or an amorphous silicon wafer.

Thus, an organic light-emitting diode display apparatus using a semiconductor substrate as the substrate 100 may be also referred to as OLED on Silicon (“OLEDoS”). Since OLEDoS uses a semiconductor substrate as the substrate 100, transistor manufacturing processes commonly used in the semiconductor technology field may be applied to a manufacturing process of a display apparatus. Therefore, formation of micro pixels and control of such pixels are possible so that OLEDoS may display ultra-high resolution images.

In some cases, the type of the substrate 100 may not be limited to a semiconductor substrate. In an embodiment, the substrate 100 may include glass, metal, or polymer resin, for example. Also, the substrate 100 may include polymer resins such as polyethersulfone, polyacrylate, polyetherimide, polyethylene naphthalate, polyethylene terephthalate, polyphenylene sulfide, polyarylate, polyimide, polycarbonate, or cellulose acetate propionate. Of course, the substrate 100 may have various modifications, such as having a multilayer structure including two layers each including such polymer resin and a barrier layer including inorganic materials (silicon oxide (SiOx), silicon nitride (SiNx), and/or silicon oxynitride (SiOxNy)) disposed between the layers. Hereinafter, the case where the substrate 100 is a silicon substrate will be described in detail.

A pixel circuit layer 110 may be disposed on the substrate 100. The pixel circuit layer 110 includes pixels, that is, a plurality of pixel circuits respectively corresponding to each of the first sub-pixel to the third sub-pixel PX1, PX2, and PX3, and each of the plurality of pixel circuits may include a transistor and/or a storage capacitor as described with reference to FIG. 6. The pixel circuit layer 110 may include at least one transistor TR and at least one insulating layer.

FIG. 7 illustrates that an organic light-emitting diode OLED as a display element is disposed on the substrate 100. That the organic light-emitting diode OLED is electrically connected to the pixel circuit PC may be understood as a pixel electrode 210 included in the organic light-emitting diode OLED being electrically connected to a transistor TR included in the pixel circuit PC. For convenience of illustration, FIG. 7 illustrates transistors TR connected to each of the first organic light-emitting diode to the third organic light-emitting diode OLED1, OLED2, and OLED3, and such transistors TR may correspond to the first transistor Td (refer to FIG. 6) described above.

The transistor TR may include a gate dielectric layer GO, a gate electrode GE, and an active region ACT. The transistor TR may be a Metal-Oxide-Semiconductor Field Effect Transistor (“MOSFET”), for example, but is not limited thereto. In an embodiment, the respective transistors TR may be separated from each other by element isolation regions disposed between the transistors TR.

The active region ACT may be disposed within the substrate 100. The active region ACT may be formed as a portion of the substrate 100. The active region ACT may be disposed to extend in a first direction, e.g., an x direction, within the substrate 100. A portion of the substrate 100 may be recessed, and the active region ACT may be disposed on the recessed substrate 100. The active region ACT may include a channel region C and a drain region D and a source region S respectively disposed on opposite sides of the channel region C. Each of the drain region D and the source region S may be a region on the substrate 100, which include a semiconductor material, doped with impurities. The channel region C may overlap the gate electrode GE.

The gate dielectric layer GO may be disposed between the gate electrode GE and the active region ACT. The gate dielectric layer GO may include inorganic insulating materials such as, e.g., silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The gate electrode GE may be disposed on the active region ACT. The gate electrode GE may be disposed to extend in one direction, e.g., a y direction, intersecting the active region ACT. A channel region C of the transistor TR may be formed in the active region ACT that intersects the gate electrode GE. That is, the gate electrode GE may overlap the channel region C of the transistor TR. The gate electrode GE may be disposed on the gate dielectric layer GO. The gate electrode GE may include a conductive material. In an embodiment, the gate electrode GE may include metal nitrides such as titanium nitride (TiN), tantalum nitride (TaN), or tungsten nitride (WN), and/or metal materials such as aluminum (Al), tungsten (W), copper (Cu), or molybdenum (Mo), or semiconductor materials such as doped polysilicon, for example. The gate electrode GE may be formed as a multilayer or single layer including the above materials.

An inter-insulating layer 111 may be disposed on the substrate 100 and may cover the transistor TR. The inter-insulating layer 111 may include at least one of an oxide, a nitride, and an oxynitride. The inter-insulating layer 111 may have a single-layer or multilayer structure.

A drain electrode DE and a source electrode SE may be disposed on the inter-insulating layer 111. The drain electrode DE and the source electrode SE may be connected to the drain region D and the source region S of the active region ACT through contact holes provided in the inter-insulating layer 111, respectively. The drain electrode DE and the source electrode SE may include materials with good conductivity. The drain electrode DE and the source electrode SE may include conductive materials including molybdenum (Mo), aluminum (Al), copper (Cu), titanium (Ti), or the like, and may be formed as a multilayer or single layer including the above materials.

A via-insulating layer 120 may be disposed on the pixel circuit layer 110. The via-insulating layer 120 may be an organic insulating layer that covers upper surfaces of the drain electrode DE and the source electrode SE and has a generally flat upper surface, serving as a planarization layer. The via-insulating layer 120 may include organic materials such as acrylic, benzocyclobutene (“BCB”), or hexamethyldisiloxane (“HMDSO”), for example. The via-insulating layer 120 is illustrated as a single layer, but is not limited thereto and may be formed as multiple layers.

A display element layer 140 may be disposed on the via-insulating layer 120. The display element layer 140 may include a first organic light-emitting diode OLED1, a second organic light-emitting diode OLED2, and a third organic light-emitting diode OLED3.

The first to third organic light-emitting diodes OLED1, OLED2, and OLED3 may include a stacked structure of a pixel electrode 210, an emission layer 220, and a counter electrode 230. The first to third organic light-emitting diodes OLED1, OLED2, and OLED3 emit light, and areas where light is emitted may be defined as first to third emission areas EA1, EA2, and EA3, respectively.

A plurality of pixel electrodes 210 may be disposed on the via-insulating layer 120. The pixel electrodes 210 may be electrically connected to the transistor TR through contact holes provided in the via-insulating layer 120. Each of the pixel electrodes 210 may include a light-transmitting conductive layer including or consisting of a light-transmitting conductive oxide such as ITO, In₂O₃, or IZO, and a reflective layer including or consisting of a metal such as Al or Ag. In an embodiment, each of the pixel electrodes 210 may have a three-layer structure of ITO/Ag/ITO, for example.

As illustrated in FIG. 7, the pixel electrodes 210 may include a first pixel electrode 210a, a second pixel electrode 210b, and a third pixel electrode 210c. The first to third pixel electrodes 210a, 210b, and 210c may be spaced apart from each other when viewed in a direction perpendicular to the substrate 100.

A pixel-defining layer 130 may be disposed on the via-insulating layer 120. The pixel-defining layer 130 may define openings 130OP respectively corresponding to the first to third sub-pixels PX1, PX2, and PX3. The openings 130OP of the pixel-defining layer 130 may expose at least a portion, e.g., a central portion, of each of the pixel electrodes 210. In an embodiment, the first to third emission areas EA1, EA2, and EA3 may be defined as areas exposed by the openings 130OP of the pixel-defining layer 130. The pixel-defining layer 130 may include organic insulating materials and/or inorganic insulating materials. The pixel-defining layer 130 may include organic materials such as polyimide or hexamethyldisiloxane (“HMDSO”), for example.

A spacer (not illustrated) for preventing mask sagging may be further included on the pixel-defining layer 130. In an embodiment, the spacer may be formed integrally with the pixel-defining layer 130. In an embodiment, the spacer and the pixel-defining layer 130 may be formed simultaneously in the same process using a halftone mask process, for example.

The emission layer 220 may be disposed on the pixel electrodes 210. The emission layer 220 may be disposed to cover the pixel electrodes 210 exposed by the openings 130OP of the pixel-defining layer 130. In an embodiment, the emission layer 220 may be formed integrally across the plurality of pixel electrodes 210.

The emission layer 220 may emit light of a predetermined color. In an embodiment, the emission layer 220 may emit green light, red light, or blue light, for example. In an alternative embodiment, the emission layer 220 may emit white light.

In an embodiment, the emission layer 220 may include relatively high molecular weight or relatively low molecular weight organic materials. The emission layer 220 may include an organic emission layer. In an embodiment, the emission layer 220 may include polymer materials such as polyphenylene vinylene (“PPV”)-based and polyfluorene-based materials, for example. The emission layer 220 may be formed by screen printing, inkjet printing, laser induced thermal imaging (“LITI”), or the like. However, the disclosure is not limited thereto, and the emission layer 220 may include inorganic emission materials or quantum dots.

In an embodiment, functional layers (not illustrated) may be disposed below and above the emission layer 220. The functional layers may include a hole injection layer (“HIL”), a hole transport layer (“HTL”), an electron transport layer (“ETL”), and/or an electron injection layer (“EIL”). Such functional layers may be integral across the plurality of pixel electrodes 210 or may be patterned to correspond to each of the plurality of pixel electrodes 210.

The counter electrode 230 may be disposed on the pixel electrodes 210 and may overlap the pixel electrodes 210. The counter electrode 230 may be disposed on the emission layer 220. The counter electrode 230 may include or consist of a conductive material having a relatively low work function. In an embodiment, the counter electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or alloys thereof, for example. In an alternative embodiment, the counter electrode 230 may further include a layer such as ITO, IZO, ZnO, or In₂O₃ on the (semi)transparent layer including the above-described materials. The counter electrode 230 may be formed integrally to cover an entirety of the substrate 100.

An encapsulation layer 300 may be disposed on the counter electrode 230. The encapsulation layer 300 may be disposed to cover the plurality of organic light-emitting diodes, that is, the first to third organic light-emitting diodes OLED1, OLED2, and OLED3. The encapsulation layer 300 may include at least one inorganic encapsulation layer and at least one organic encapsulation layer. In an embodiment, the encapsulation layer 300 may include a first inorganic encapsulation layer 310, an organic encapsulation layer 320 on the first inorganic encapsulation layer 310, and a second inorganic encapsulation layer 330.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include polymer-based materials. Polymer-based materials may include acrylic resins, epoxy resins, polyimide, and polyethylene. In an embodiment, the organic encapsulation layer 320 may include acrylate. The organic encapsulation layer 320 may be formed by curing monomers or applying polymers. The organic encapsulation layer 320 may have transparency.

Although not illustrated, a touch sensor layer may be disposed on the encapsulation layer 300, and an optical functional layer may be disposed on the touch sensor layer. The touch sensor layer may acquire coordinate information according to external input, e.g., touch events. The optical functional layer may reduce reflectance of light (external light) incident toward the display apparatus from the outside, and/or may improve color purity of light emitted from the display apparatus. In an embodiment, the optical functional layer may include a retarder and/or a polarizer. The retarder may be a film type or a liquid crystal coating type, and may include a λ/2 retarder and/or a λ/4 retarder. The polarizer may also be a film type or a liquid crystal coating type. The film type may include a stretched synthetic resin film, and the liquid crystal coating type may include liquid crystals arranged in a predetermined arrangement. The retarder and the polarizer may further include a protective film.

An adhesive member may be disposed between the touch sensor layer and the optical functional layer. The adhesive member may employ any general one known in the art without limitation. In an embodiment, the adhesive member may be a pressure sensitive adhesive (“PSA”).

FIG. 8 is a cross-sectional view showing an embodiment of a manufacturing apparatus for a display apparatus. In an embodiment, a manufacturing apparatus 2 of a display apparatus may be used to manufacture the display apparatus described above.

The manufacturing apparatus 2 of a display apparatus may include a chamber 90, a first support portion 20, a second support portion 30, a mask assembly MA, a deposition source 50, a magnetic force portion 60, a vision portion 70, and a pressure control portion 80.

The chamber 90 may have a space formed therein, and a display substrate DS and a mask assembly MA may be accommodated therein. At this time, a portion of the chamber 90 may be opened, and a gate valve 91 may be installed in the opened portion of the chamber 90. In such a case, the opened portion of the chamber 90 may be opened or closed according to operation of the gate valve 91.

The display substrate DS may mean a display substrate DS during manufacture of a display apparatus, in which at least one layer among an organic layer, an inorganic layer, and a metal layer is deposited on the substrate 100 described above. In an alternative embodiment, the display substrate DS may be the substrate 100 on which none of an organic layer, an inorganic layer, and a metal layer has been deposited yet.

The first support portion 20 may support the display substrate DS. At this time, the first support portion 20 may be in the form of a plate fixed inside the chamber 90. In another embodiment, the first support portion 20 may be in the form of a shuttle on which the display substrate DS is seated and which may perform linear motion within the chamber 90. In another embodiment, the first support portion 20 may include an electrostatic chuck or an adhesive chuck that is fixed to the chamber 90 or disposed in the chamber 90 to be movable within the chamber 90.

The second support portion 30 may support the mask assembly MA. The second support portion 30 may be disposed inside the chamber 90. The second support portion 30 may be capable of performing fine adjustment of a position of the mask assembly MA. The second support portion 30 may include a separate driving unit or alignment unit to enable movement of the mask assembly MA in different directions from each other.

In an embodiment, the second support portion 30 may be in the form of a shuttle. In such a case, the second support portion 30 may have the mask assembly MA seated thereon and may transport the mask assembly MA. In an embodiment, the second support portion 30 may move outside the chamber 90, and after the mask assembly MA is seated, may enter the chamber 90 from outside the chamber 90, for example.

In such cases, it is also possible for the first support portion 20 and the second support portion 30 to be formed integrally. In such a case, the first support portion 20 and the second support portion 30 may include a movable shuttle. The first support portion 20 and the second support portion 30 include a structure that fixes the mask assembly MA and the display substrate DS with the display substrate DS seated on the mask assembly MA, and it is also possible to simultaneously move the display substrate DS and the mask assembly MA linearly.

However, hereinafter, for convenience of description, detailed description will be focused on forms where the first support portion 20 and the second support portion 30 are distinguished from each other and disposed at different positions from each other, and the first support portion 20 and the second support portion 30 are disposed inside the chamber 90.

The deposition source 50 may be disposed to face the mask assembly MA. A deposition material may be accommodated in the deposition source 50, and the deposition material may be evaporated or sublimated by applying heat to the deposition material. The deposition source 50 may be fixed inside the chamber 90 or may be disposed inside the chamber 90 to enable linear motion along one direction.

The mask assembly MA may be disposed inside the chamber 90. The mask assembly MA may include a mask frame MF and a mask sheet MS. This will be described in detail below. The deposition material may pass through the mask assembly MA and be deposited on the display substrate DS.

The magnetic force portion 60 may be disposed inside the chamber 90 to face the display substrate DS and/or the mask assembly MA. The magnetic force portion 60 may apply magnetic force to the mask assembly MA to force the mask assembly MA toward the display substrate DS. In particular, the magnetic force portion 60 may not only prevent sagging of the mask sheet MS but also bring the mask sheet MS close to the display substrate DS. Also, the magnetic force portion 60 may uniformly maintain a gap between the mask sheet MS and the display substrate DS.

The vision portion 70 is disposed in the chamber 90 and may capture positions of the display substrate DS and the mask assembly MA. At this time, the vision portion 70 may include a camera that captures the display substrate DS and the mask assembly MA. Based on images captured by the vision portion 70, positions of the display substrate DS and the mask assembly MA may be determined, and deformation of the mask assembly MA may be confirmed. Also, based on the images, a position of the display substrate DS may be finely adjusted at the first support portion 20 or a position of the mask assembly MA may be finely adjusted at the second support portion 30. However, hereinafter, detailed description will be focused on a case where positions of the display substrate DS and the mask assembly MA are aligned by finely adjusting a position of the mask assembly MA at the second support portion 30.

The pressure control portion 80 may be connected to the chamber 90 to control pressure inside the chamber 90. In an embodiment, the pressure control portion 80 may control pressure inside the chamber 90 to be identical to or similar to atmospheric pressure, for example. Also, the pressure control portion 80 may control pressure inside the chamber 90 to be identical to or similar to a vacuum state.

The pressure control portion 80 may include a connection pipe 81 connected to the chamber 90 and a pump 82 installed in the connection pipe 81. According to operation of the pump 82, external air may be introduced through the connection pipe 81 or gas inside the chamber 90 may be guided to the outside through the connection pipe 81.

Looking at a method of manufacturing a display apparatus using the manufacturing apparatus 2 of a display apparatus as described above, first, a display substrate DS may be prepared.

The pressure control portion 80 may maintain the inside of the chamber 90 in a state identical to or similar to atmospheric pressure, and the gate valve 91 may operate to open the opened portion of the chamber 90.

Thereafter, the display substrate DS may be loaded from outside the chamber 90 to the inside. The display substrate DS may be loaded into the chamber 90 in various ways. In an embodiment, the display substrate DS may be loaded from outside the chamber 90 to inside the chamber 90 through a robot arm or the like disposed outside the chamber 90, for example. In an embodiment, when the first support portion 20 is formed in a shuttle form, it is also possible for the first support portion 20 to be taken out from inside the chamber 90 to outside the chamber 90, then seat the display substrate DS on the first support portion 20 through a separate robot arm or the like disposed outside the chamber 90, and for the first support portion 20 to be loaded from outside the chamber 90 to inside the chamber 90.

The mask assembly MA may be in a state disposed inside the chamber 90 as described above. In an embodiment, it is also possible for the mask assembly MA to be loaded from outside the chamber 90 to inside the chamber 90 identically or similarly to the display substrate DS.

When the display substrate DS is loaded into the chamber 90, the display substrate DS may be seated on the first support portion 20. The vision portion 70 may capture positions of the display substrate DS and the mask assembly MA. Positions of the display substrate DS and the mask assembly MA may be determined based on images captured by the vision portion 70. The manufacturing apparatus 2 of a display apparatus may be equipped with a separate control unit (not illustrated) to determine positions of the display substrate DS and the mask assembly MA.

When determination of positions of the display substrate DS and the mask assembly MA is completed, the second support portion 30 may finely adjust a position of the mask assembly MA.

Thereafter, the deposition source 50 operates to supply deposition material toward the mask assembly MA, and the deposition material that passed through a plurality of deposition holes of the mask sheet MS may be deposited on the display substrate DS. The deposition source 50 may move parallel to the display substrate DS and the mask assembly MA, or the display substrate DS and the mask assembly MA may move parallel to the deposition source 50. That is, the deposition source 50 may move relatively with respect to the display substrate DS and the mask assembly MA. The pump 82 may suck gas inside the chamber 90 and discharge the same to the outside, thereby maintaining pressure inside the chamber 90 in a form identical to or similar to vacuum.

As described above, the deposition material supplied from the deposition source 50 passes through the mask assembly MA and is deposited on the display substrate DS, thereby forming at least one of a plurality of layers, e.g., an organic layer, an inorganic layer, and a metal layer, stacked in a display apparatus.

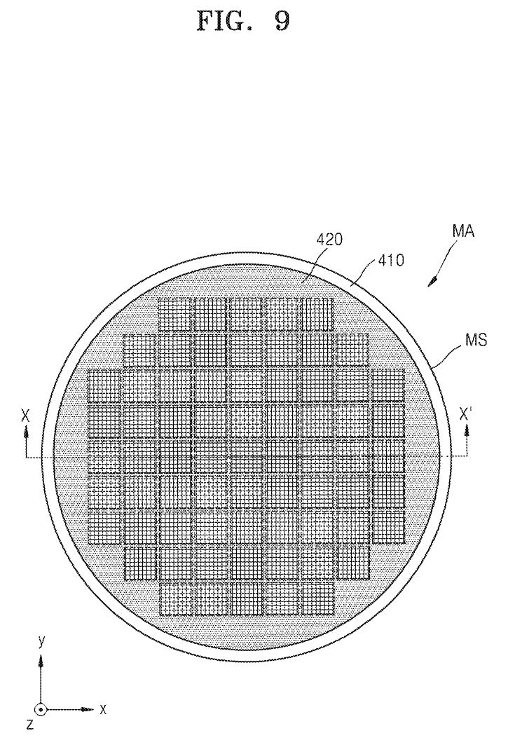

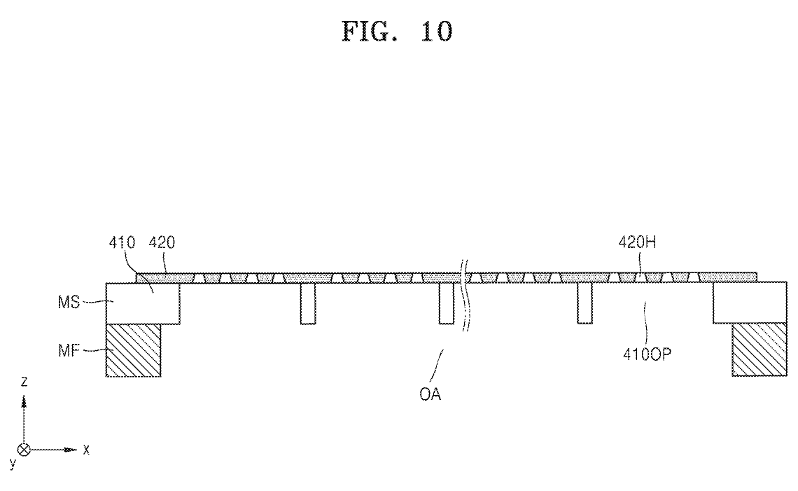

FIG. 9 is a schematic plan view of an embodiment of a mask assembly. FIG. 10 is a schematic cross-sectional view of an embodiment of a mask assembly taken along line X-X' of FIG. 9.

Referring to FIGS. 9 and 10, the mask assembly MA may include a mask frame MF and a mask sheet MS.

The mask frame MF is a frame that supports the mask sheet MS, and may be a frame that defines an opening area OA at the center thereof. In an embodiment, the mask frame MF may be a circular frame, and the opening area OA may also be defined as circular. However, the shape of the mask frame MF is not limited thereto and may be various polygonal shapes. Hereinafter, for convenience of description, the case where the mask frame MF is a circular frame will be mainly described.

The mask sheet MS may be installed on the mask frame MF. The opening area (also referred as a central opening area) OA of the mask frame MF may be covered by the mask sheet MS. In an embodiment, the mask sheet MS may be fixed to the mask frame MF by welding. Also, in an embodiment, the mask sheet MS may have a circular shape corresponding to the shape of the opening area OA of the mask frame MF.

The mask sheet MS may include a body portion 410 and a sheet portion 420.

The body portion 410 may include a silicon material. In an embodiment, the body portion 410 may include at least one material among silicon oxide (SiOx), silicon nitride (SiNx), and silicon oxynitride (SiOxNy), for example.

The body portion 410 may cover the opening area OA of the mask frame MF. The body portion 410 may correspond to a shape of the mask frame MF. In an embodiment, when the mask frame MF has a circular frame, the body portion 410 may have a circular shape, for example. However, the disclosure is not limited thereto, and the body portion 410 may have various polygonal shapes. Hereinafter, for convenience of description, the case where the body portion 410 has a circular shape will be mainly described.

In an embodiment, a body opening 410OP may be defined in the body portion 410. A plurality of body openings 410OP may be provided, and may be spaced apart in a first direction (x direction) and a second direction (y direction), for example. In other words, the body portion 410 may include lattice-shaped ribs to define a plurality of body openings 410OP.

In an embodiment, each of the plurality of body openings 410OP may be defined to have a quadrangular shape, e.g., rectangular shape. Each of such plurality of body openings 410OP may correspond to a shape of a display panel. That is, each of the plurality of body openings 410OP may correspond to a shape of a cell.

The sheet portion 420 may be disposed on the body portion 410. The sheet portion 420 may be disposed on the body portion 410 to cover the body opening 410OP.

In an embodiment, the sheet portion 420 may include a metal material. In an embodiment, the sheet portion 420 may include at least one of aluminum (Al), copper (Cu), titanium (Ti), and molybdenum (Mo), for example. In another embodiment, the sheet portion 420 may include an inorganic material. In an embodiment, the sheet portion 420 may include at least one material among silicon oxide (SiOx), silicon nitride (SiNx), and silicon oxynitride (SiOxNy), for example.

In an embodiment, a plurality of deposition holes 420H overlapping the body opening 410OP may be defined in the sheet portion 420. In an embodiment, one body opening 410OP may overlap a plurality of deposition holes 420H, for example. Shapes of the plurality of deposition holes 420H may correspond to a shape of a deposition pattern to be deposited on the display substrate DS. In an embodiment, the plurality of deposition holes 420H may have shapes corresponding to emission layer patterns of pixels to be deposited on the display substrate DS, for example. Accordingly, deposition material may pass through the plurality of deposition holes 420H to form emission layers on the display substrate DS.

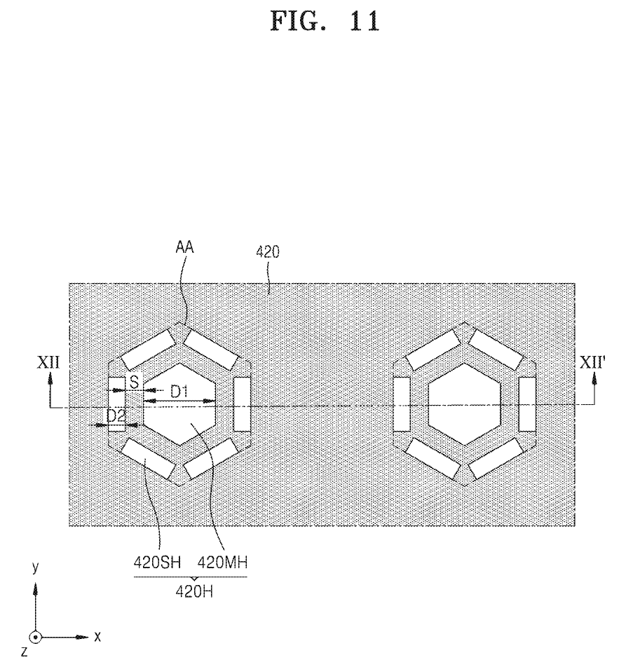

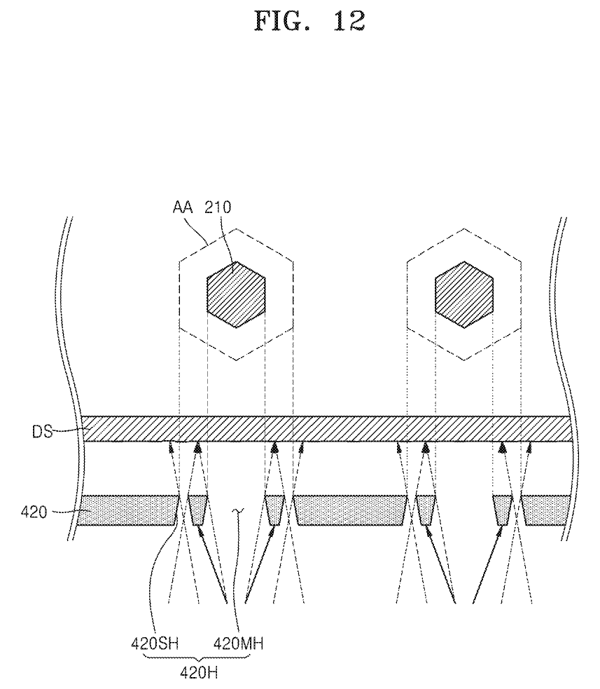

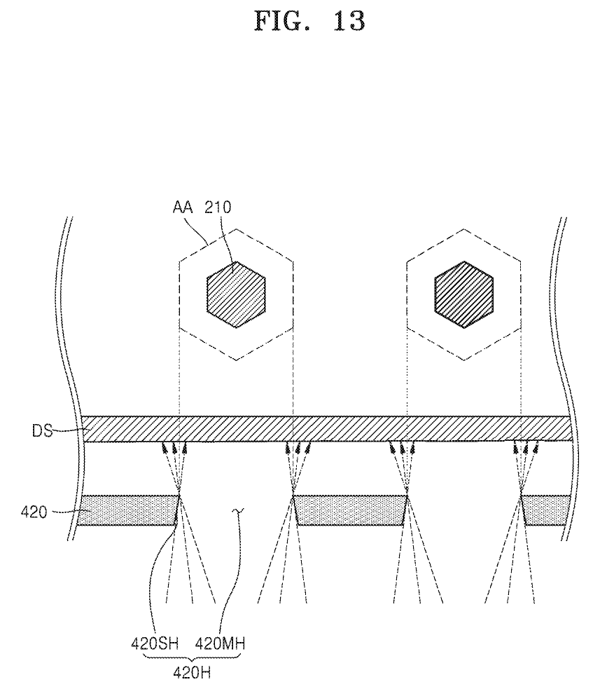

FIG. 11 is a schematic plan view of an embodiment of a sheet portion. FIG. 11 illustrates an enlarged view of some of the deposition holes illustrated in FIG. 9. FIG. 12 is a schematic cross-sectional view of an embodiment of a sheet portion taken along line XII-XII’ of FIG. 11. FIG. 12 illustrates an enlarged view of some of the deposition holes illustrated in FIG. 10. FIG. 13 is a schematic cross-sectional view of a sheet portion according to a comparative example.

Referring to FIGS. 11 and 12, each of the plurality of deposition holes 420H may be a hole for depositing a deposition area AA on the display substrate DS. In an embodiment, the deposition area AA may be an area where the emission layer 220 described above is deposited. That is, the deposition hole 420H may be a hole for depositing the emission layer 220. FIGS. 11 and 12 illustrate a deposition area AA for an emission layer 220 of any one of the first to third light-emitting diodes. In an embodiment, the deposition area AA illustrated in FIGS, for example. 11 and 12 may mean an area where emission layers 220 of the first organic light-emitting diode OLED1, e.g., emission layers 220 that emit green light, are deposited. In an embodiment, it will be understood that emission layers 220 of the second organic light-emitting diode OLED2, e.g., emission layers 220 that emit red light, may be disposed between the deposition areas AA.

In an embodiment, each of the plurality of deposition holes 420H may include a main hole 420MH and a sub-hole 420SH.

In an embodiment, the main hole 420MH may be provided in a shape corresponding to a shape of the pixel electrode 210 exposed by the pixel-defining layer 130. In an embodiment, as illustrated in FIG. 12, the pixel electrode 210 exposed by the pixel-defining layer 130 may be provided in a hexagonal shape, and the main hole 420MH may be provided in a hexagonal shape, for example. However, the disclosure is not limited thereto, and it will be understood that the main hole 420MH may be provided in other polygonal or circular shapes to cover the exposed pixel electrode 210.

Also, in an embodiment, a size of the main hole 420MH may be identical to a size of the pixel electrode 210 exposed by the pixel-defining layer 130. In other words, a width D1 of the main hole 420MH may be identical to a width of the pixel electrode 210 exposed by the pixel-defining layer 130. Accordingly, the main hole 420MH may allow deposition material to pass through to cover the exposed pixel electrode 210 in the display substrate DS, thereby depositing the emission layer 220.

The sub-hole 420SH may be disposed radially outward from the main hole 420MH. In an embodiment, the sub-hole 420SH may be disposed to surround a peripheral edge of the main hole 420MH. At this time, the sub-hole 420SH may be spaced apart from the peripheral edge of the main hole 420MH by a predetermined distance.

The sub-hole 420SH may have a size that is less than a size of the main hole 420MH. In an embodiment, a radial width D1 of the main hole 420MH may be greater than a radial width D2 of the sub-hole 420SH, for example.

In an embodiment, a plurality of sub-holes 420SH may be provided. In an embodiment, when the main hole 420MH is provided as a polygon, the sub-holes 420SH may be provided in a number corresponding to the number of edges of the polygon, and the plurality of sub-holes 420SH may be defined to respectively face their corresponding edges of the polygon, for example. In an embodiment, each of the plurality of sub-holes 420SH may be provided in a quadrangular form, e.g., rectangular form parallel to an edge of the polygon. FIG. 11 illustrates a main hole 420MH having a hexagonal shape and six sub-holes 420SH.

Also, in an embodiment, a distance S between the main hole 420MH and the sub-hole 420SH may be less than a radial width D2 of the sub-hole 420SH. Specifically, a distance from a peripheral edge of the main hole 420MH to a perimeter of the sub-hole 420SH may be less than a radial width D2 of the sub-hole 420SH.

In an embodiment, deposition material may pass through the main hole 420MH and the sub-hole 420SH to be deposited in the deposition area AA on the display substrate DS. The deposition material that passed through the main hole 420MH may cover the exposed pixel electrode 210, and the deposition material that passed through the sub-hole 420SH may enable deposition material to be deposited around the exposed pixel electrode 210. Accordingly, an emission layer 220 of one sub-pixel may be formed. In such a case, in an embodiment, the main hole 420MH and the sub-hole 420SH may be defined within the deposition area AA. In an embodiment, the sheet portion 420 may be disposed such that an outer perimeter of the sub-hole 420SH is disposed to overlap a perimeter of the deposition area AA, and then deposition may be performed, for example.

Cross-sections of the sheet portion 420 defining the main hole 420MH and the sub-hole 420SH may be tapered. In an embodiment, as illustrated in FIG. 12, cross-sections of the sheet portion 420 may be tapered such that widths of the main hole 420MH and the sub-hole 420SH decrease in a direction toward the display substrate DS, for example.

By embodiments of the disclosure, deposition quality may be improved compared to a case where the deposition hole 420H is provided as a single opening. FIG. 13 illustrates a case where the deposition hole 420H is provided as a single opening. Referring to FIG. 13, deposition material ejected from a deposition source at a relatively small incident angle may be deposited beyond the deposition area AA, causing a shadow phenomenon. Referring to FIG. 12, in embodiments of the disclosure, deposition material ejected at relatively small incident angles may not pass through the main hole 420MH and the sub-hole 420SH. That is, deposition material having relatively large incident angles (e.g., ejected more vertically) may pass through the main hole 420MH and the sub-hole 420SH to be deposited on the display substrate DS. Accordingly, as illustrated in FIG. 12, most of the deposition material may be deposited within the deposition area AA, and a shadow phenomenon may be prevented.

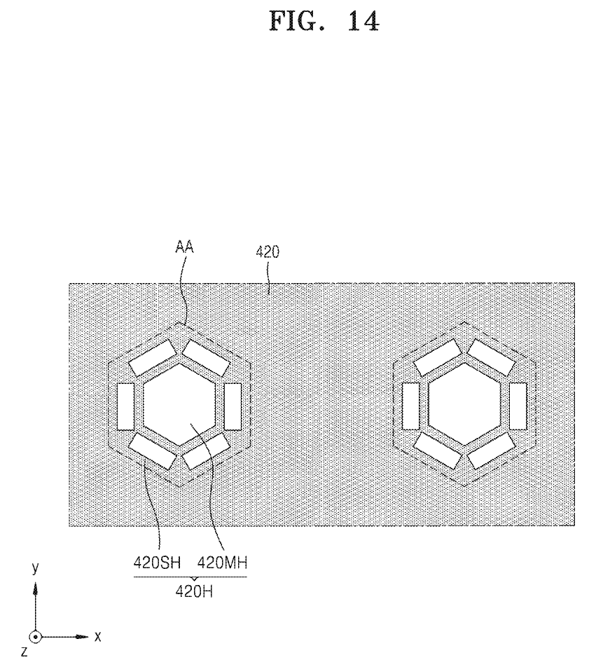

FIGS. 14-16 are schematic plan views of embodiments of sheet portions. The sheet portions in the illustrated embodiments are similar to the sheet portion described above, so hereinafter, only differences will be mainly described for convenience of description.

Referring to FIG. 14, the deposition hole 420H may include a main hole 420MH and a sub-hole 420SH. The sub-hole 420SH may be defined to surround a perimeter of the main hole 420MH. Also, the sub-hole 420SH may be spaced apart from the perimeter of the main hole 420MH by a predetermined distance.

In an embodiment, deposition material may pass through the main hole 420MH and the sub-hole 420SH to be deposited in the deposition area AA on the display substrate DS. The deposition material that passed through the main hole 420MH may cover the exposed pixel electrode 210, and the deposition material that passed through the sub-hole 420SH may enable deposition material to be deposited around the exposed pixel electrode 210. Accordingly, an emission layer 220 of one sub-pixel may be formed. In such a case, in an embodiment, the main hole 420MH and the sub-hole 420SH may be defined within the deposition area AA. In an embodiment, the sheet portion 420 may be disposed such that the sub-hole 420SH is defined to be spaced inward from a perimeter of the deposition area AA, and then deposition may be performed. In other words, the sub-hole 420SH may be defined between a perimeter of the deposition area AA and a peripheral edge of the main hole 420MH. Accordingly, deposition of deposition material beyond the deposition area AA may be further prevented.

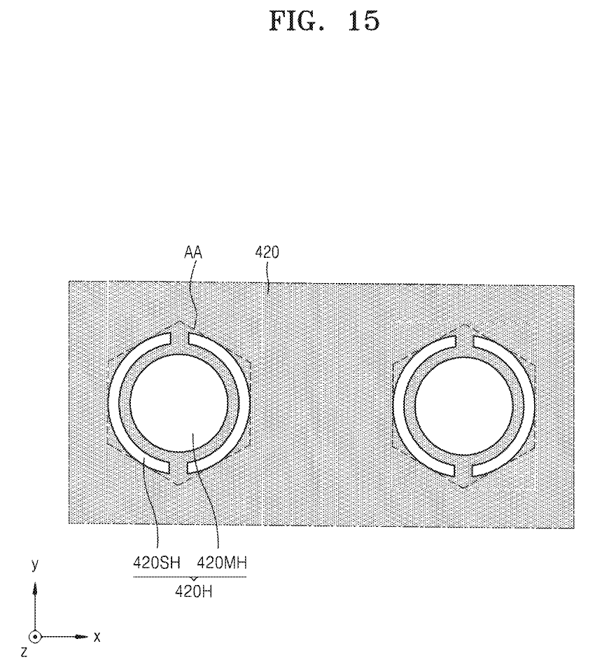

Referring to FIG. 15, in an embodiment, the main hole 420MH may be provided in a circular shape. The sub-hole 420SH may be defined along a perimeter of the main hole 420MH. In an embodiment, a plurality of sub-holes 420SH may be provided, and each of the plurality of sub-holes 420SH may be provided in a segmented ring shape. In an embodiment, as illustrated in FIG. 15, two sub-holes 420SH may be provided, and each of the sub-holes 420SH may have a half-ring shape, for example. However, the disclosure is not necessarily limited thereto, and it will be understood that two or more sub-holes 420SH may be provided. In an embodiment, four sub-holes 420SH may be provided, and each of the sub-holes 420SH may be provided in a quarter-ring shape, for example.

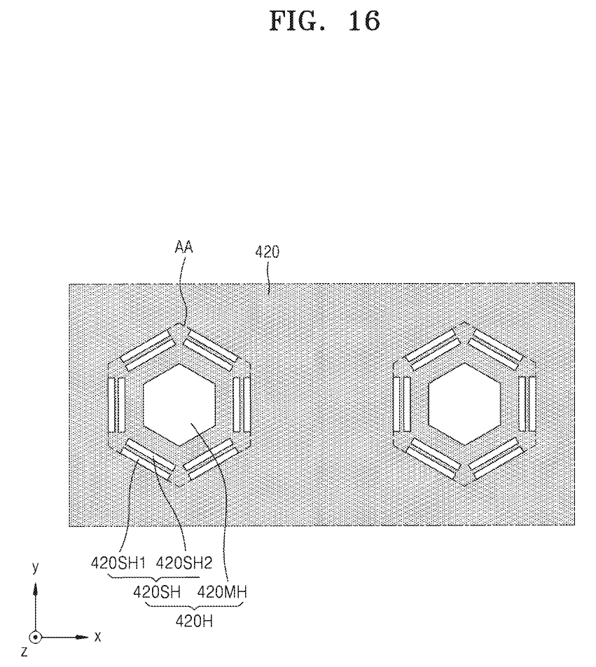

Referring to FIG. 16, in an embodiment, the sub-hole 420SH may include a first sub-hole 420SH1 and a second sub-hole 420SH2. The first sub-hole 420SH1 may be defined to surround the main hole 420MH. Also, a plurality of first sub-holes 420SH1 may be provided, and the plurality of first sub-holes 420SH1 may be spaced apart from each other along a perimeter of the main hole 420MH. That is, a hole group of a first row composed of the plurality of first sub-holes 420SH1 may be defined to surround the main hole 420MH.

The second sub-hole 420SH2 may be disposed outside the first sub-hole 420SH1 to surround the first sub-holes 420SH1. A plurality of second sub-holes 420SH2 may be provided, and the plurality of second sub-holes 420SH2 may be spaced apart from each other along outer perimeters of the plurality of first sub-holes 420SH1. That is, a hole group of a second row composed of the plurality of second sub-holes 420SH2 may be disposed to surround the hole group of the first row.

At this time, in an embodiment, each of the second sub-holes 420SH2 may be defined to face each of the first sub-holes 420SH1. As the sub-hole 420SH includes the first sub-hole 420SH1 and the second sub-hole 420SH2, deposition material ejected at relatively small incident angles may be further prevented from passing through the sheet portion 420, and deposition material having relatively large incident angles (e.g., ejected more vertically) may more easily pass through the sheet portion 420.

By embodiments, a shadow phenomenon may be prevented when depositing deposition material on a display substrate, and deposition quality may be improved.

Effects of the disclosure are not limited to the effects mentioned above, and other effects not mentioned will be clearly understood by those skilled in the art from the description of the claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A mask assembly comprising:
a mask sheet in which a plurality of deposition holes are defined; and
a mask frame supporting the mask sheet,
wherein each of the plurality of deposition holes comprises:
a main hole and
a sub-hole defined radially outward from the main hole.

2. The mask assembly of claim 1,
wherein the sub-hole surrounds a peripheral edge of the main hole.

3. The mask assembly of claim 1,
wherein the sub-hole is provided in plural, and the plurality of sub-holes are spaced apart along a perimeter of the main hole.

4. The mask assembly of claim 3,
wherein the main hole has a polygonal shape,
wherein the plurality of sub-holes correspond to a number of edges of the polygon, and the plurality of sub-holes respectively face the edges of the polygon.

5. The mask assembly of claim 3,
wherein the main hole has a circular shape, and
wherein the sub-hole has a segmented ring shape.

6. The mask assembly of claim 2,
wherein the sub-hole is provided in plural, and the plurality of sub-holes comprise a first sub-hole surrounding the main hole and a second sub-hole defined outside the first sub-hole and surrounding the first sub-hole.

7. The mask assembly of claim 1,
wherein a radial width of the main hole is greater than a radial width of the sub-hole.

8. The mask assembly of claim 1,
wherein a distance from a perimeter of the main hole to a perimeter of the sub-hole is less than a radial width of the sub-hole.

9. A method for manufacturing a display apparatus, the method comprising:
disposing a display substrate and a deposition source to face the display substrate;
disposing a mask assembly between the display substrate and the deposition source; and
depositing a deposition material from the deposition source on a deposition area on the display substrate through a deposition hole of the mask assembly,
wherein the deposition hole corresponding to the deposition area comprises:
a main hole and a sub-hole defined radially outward from the main hole, wherein the main hole and the sub-hole are disposed within the deposition area in a plan view.

10. The method of claim 9,
further comprising forming an emission layer of a sub-pixel by depositing the deposition material in the deposition area.

11. The method of claim 10,
wherein the emission layer of the sub-pixel is formed by depositing the deposition material which passed through the main hole and the sub-hole in the deposition area.

12. The method of claim 11,
wherein the display substrate comprises a pixel electrode disposed below the emission layer of the sub-pixel, and a size of the main hole is identical to a size of the pixel electrode.

13. The method of claim 9,
wherein an outer perimeter of the sub-hole overlaps a perimeter of the deposition area.

14. The method of claim 9,
wherein an outer perimeter of the sub-hole is spaced inward from a perimeter of the deposition area.

15. The method of claim 9,
wherein the sub-hole surrounds a peripheral edge of the main hole.

16. The method of claim 9,
wherein the sub-hole is provided in plural, and the plurality of sub-holes are spaced apart along a perimeter of the main hole.

17. The method of claim 16,
wherein the main hole has a polygonal shape,
wherein a plurality of sub-holes correspond to a number of edges of the polygon, and each of the plurality of sub-holes faces each of the edges of the polygon.

18. The method of claim 16,
wherein the main hole has a circular shape, and
wherein the sub-hole has a segmented ring shape.

19. The method of claim 16,
wherein the plurality of sub-holes comprises a first sub-hole surrounding the main hole and a second sub-hole defined outside the first sub-hole and surrounding the first sub-hole.

20. A method for manufacturing an electronic device, the method comprising:
disposing a display substrate and a deposition source to face the display substrate;
disposing a mask assembly between the display substrate and the deposition source; and
depositing a deposition material from the deposition source on a deposition area on the display substrate through a deposition hole of the mask assembly,
wherein the deposition hole corresponding to the deposition area comprises:
a main hole and a sub-hole defined radially outward from the main hole, and
wherein the main hole and the sub-hole are disposed within the deposition area.
